(19) United States
(12) Patent Application Publication
(10) Pub. No.: US 2024/0292682 A1
(43) Pub. Date: Aug. 29, 2024

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yucheng CHAN, Beijing (CN); Chengchung YANG, Beijing (CN); Yunpeng ZHANG, Beijing (CN); Yangzhong JING, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/022,999

(22) PCT Filed: Apr. 20, 2022
(86) PCT No.: PCT/CN2022/087979

§ 371 Date: Feb. 24, 2023

(51) Int. Cl. H10K 59/131; H10K 59/12; H10K 59/124; H10K 102/00

(52) U.S. Cl. CPC H10K 59/131; H10K 59/1201; H10K 59/124; H10K 2102/311

(57) ABSTRACT

A display panel including: a first flexible layer; a second flexible layer, provided on a side of the first flexible layer; and a signal line, provided between the first flexible layer and the second flexible layer. The second flexible layer is provided with a first through hole, and the first through hole exposes a surface of the signal line. An inorganic layer covers a surface of the second flexible layer and a sidewall of the first through hole. The inorganic layer is provided with a second through hole, and the second through hole exposes a surface of the signal line. A first conductive layer includes an adapter line, and the adapter line covers at least a sidewall of the second through hole and the exposed surface of the signal line.

### CROSS REFERENCE

The present disclosure is a National Stage of International Application No. PCT/CN2022/087979 filed on Apr. 20, 2022, the entire contents of which are incorporated herein by reference.

### TECHNICAL FIELD

The present disclosure relates to the field of display technology, and in particular, to a display panel, a method for manufacturing a display panel, and a display device.

### BACKGROUND

In recent years, the development of full screen has been very rapid, which puts forward new needs for the modality of the screen. For full-screen display, it is very important to reduce the screen frame.

The above information disclosed in the background section is only for enhancement of understanding of the background of the present disclosure. Accordingly, it may contain information that does not form the related art that is already known in the art to a person of ordinary skill in the art.

### SUMMARY

According to a first aspect of the present disclosure, there is provided a display panel, including:
a first flexible layer;
a second flexible layer, provided on a side of the first flexible layer;
a signal line, provided between the first flexible layer and the second flexible layer, where the second flexible layer is provided with a first through hole, and the first through hole exposes a surface of the signal line away from the first flexible layer;
an inorganic layer, covering a surface of the second flexible layer away from the first flexible layer and a sidewall of the first through hole, where the inorganic layer is provided with a second through hole, an orthographic projection of the second through hole on the first flexible layer is located within an orthographic projection of the first through hole on the first flexible layer, and the second through hole exposes the surface of the signal line away from the first flexible layer;
a first conductive layer, including an adapter line, where the adapter line covers at least a sidewall of the second through hole and the surface of the signal line exposed by the second through hole.

In at least one embodiment of the present disclosure, the display panel further includes:
an insulation layer, provided on a side of the inorganic layer away from the first flexible layer, where the insulation layer is provided with a third through hole, and the third through hole communicates with the second through hole;
an orthographic projection of the second through hole on the first flexible layer is located within an orthographic projection of the third through hole on the first flexible layer;
the second through hole is provided with a second hole wall, the third through hole is provided with a third hole wall, the second hole wall and the third hole wall are connected to each other to form a through hole wall, and the through hole wall is at least provided with a stepped portion.

In at least one embodiment of the present disclosure, the display panel further includes:
an insulation layer, provided on a side of the inorganic layer away from the first flexible layer, where the insulation layer is provided with a third through hole, and the third through hole communicates with the second through hole;
an orthographic projection of the second through hole on the first flexible layer is located within an orthographic projection of the third through hole on the first flexible layer;
the second through hole is provided with a second hole wall, the third through hole is provided with a third hole wall, a first distance parallel to a direction of the first flexible layer is provided between an end of the second hole wall away from the first flexible layer and an end of the third hole wall close to the flexible layer, and the first distance is greater than or equal to 0;
the adapter line covers at least part of a surface of the insulation layer away from the first flexible layer, and at least covers the second hole wall and the third hole wall.

In at least one embodiment of the present disclosure, the insulation layer includes a first gate insulation layer, and the first gate insulation layer is provided with the third through hole;
the first conductive layer further includes a gate of a transistor and a first plate of a capacitor;
the adapter line covers at least part of a surface of the first gate insulation layer away from the first flexible layer.

In at least one embodiment of the present disclosure, the insulation layer includes a first gate insulation layer and a second gate insulation layer provided in sequence along a direction away from the first flexible layer, and the third through hole is provided in the first gate insulation layer and the second gate insulation layer;
the first conductive layer includes a second plate of a capacitor;
the adapter line covers at least part of a surface of the second gate insulation layer away from the first flexible layer.

In at least one embodiment of the present disclosure, the third through hole includes a first through sub-hole and a second through sub-hole;
the first through sub-hole is provided in the first gate insulation layer, and the second through sub-hole is provided in the second gate insulation layer;
an orthographic projection of the first through sub-hole on the first flexible layer is located within an orthographic projection of the second through sub-hole on the first flexible layer;
the first through sub-hole is provided with a first sub-hole wall, the second through sub-hole is provided with a second sub-hole wall, a second distance parallel to the direction of the first flexible layer is provided between an end of the first sub-hole wall away from the first flexible layer and an end of the second sub-hole wall close to the first flexible layer, and the second distance is greater than or equal to zero.

In at least one embodiment of the present disclosure, the display panel further includes:
an active layer, provided between the inorganic layer and the insulation layer;
an interlayer dielectric layer, provided on a side of the first conductive layer away from the first flexible layer;
a third conductive layer, provided on a side of the interlayer dielectric layer away from the first flexible layer, where the third conductive layer includes a source and a drain of a transistor, the source and the drain are connected to the active layer, and the third conductive layer is connected to the adapter line;
the signal line is configured to provide a power supply voltage to a pixel circuit.

In at least one embodiment of the present disclosure, the display panel further includes:
a buffer layer, provided between the first flexible layer and the second flexible layer;
the signal line is provided on a side of the buffer layer close to the first flexible layer; or
the signal line is provided on a side of the buffer layer away from the first flexible layer.

In at least one embodiment of the present disclosure, the first distance is not less than 3 μm, and/or the second distance is not smaller than 3 μm.

According to a second aspect of the present disclosure, there is provided a method for manufacturing a display panel, including:
forming a first flexible layer;
forming a signal line on a side of the first flexible layer;
forming a second flexible layer on a side of the signal line away from the first flexible layer;
forming a first through hole in the second flexible layer, where the first through hole exposes a surface of the signal line away from the first flexible layer;
forming an inorganic layer on a side of the second flexible layer away from the first flexible layer, where the inorganic layer covers a surface of the second flexible layer away from the first flexible layer and a sidewall of the first through hole;
forming a first conductive layer, where the first conductive layer includes an adapter line;
where, a second through hole is formed in the inorganic layer, an orthographic projection of the second through hole on the first flexible layer is located with an orthographic projection of the first through hole on the first flexible layer, and the second through hole exposes the surface of the signal line away from the first flexible layer;
the adapter line covers at least a sidewall of the second through hole and the surface of the signal line exposed by the second through hole.

In at least one embodiment of the present disclosure, before forming the first conductive layer, the method further includes:
forming an insulation layer on a side of the inorganic layer away from the first flexible layer;
where, a third through hole is formed in the insulation layer, the insulation layer covers at least part of a surface of the inorganic layer, and the third through hole communicates with the second through hole;
an orthographic projection of the second through hole on the first flexible layer is located within an orthographic projection of the third through hole on the first flexible layer;
the second through hole is provided with a second hole wall, the third through hole is provided with a third hole wall, a first distance parallel to a direction of the first flexible layer is provided between an end of the second hole wall away from the first flexible layer and an end of the third hole wall close to the flexible layer, and the first distance is greater than or equal to 0;
the adapter line covers at least part of a surface of the insulation layer away from the first flexible layer, and at least covers the second hole wall and the third hole wall.

In at least one embodiment of the present disclosure, the forming the insulation layer on the side of the inorganic layer away from the first flexible layer includes:
forming a first gate insulation layer on a side of the inorganic layer away from the first flexible layer, where the first gate insulation layer covers at least part of a surface of the inorganic layer away from the first flexible layer;
forming a second gate insulation layer on a side of the first gate insulation layer away from the first flexible layer, where the second gate insulation layer covers at least a part of a surface of the first gate insulation layer away from the first flexible layer;
where, a first through sub-hole is formed in the first gate insulation layer, a second through sub-hole is formed in the second gate insulation layer, and the first through sub-hole and the second through sub-hole form the third through hole;
an orthographic projection of the second through hole on the first flexible layer is located within an orthographic projection of the first through sub-hole on the first flexible layer, and an orthographic projection of the first through sub-hole on the first flexible layer is located within an orthographic projection of the second through sub-hole on the first flexible layer; and
the first through sub-hole is provided with a first sub-hole wall, the second through sub-hole is provided with a second sub-hole wall, a second distance parallel to the direction of the first flexible layer is provided between an end of the first sub-hole wall away from the first flexible layer and an end of the second sub-hole wall close to the first flexible layer, and the second distance is greater than or equal to zero.

According to a third aspect of the present disclosure, there is provided a display device, including the display panel as described in the first aspect.

### BRIEF DESCRIPTION OF THE DRAWINGS

The above and other features and advantages of the present disclosure will become more apparent by describing the example embodiments in detail with reference to the in accompanying drawings.

FIG. 1 is a schematic structural diagram of a display panel according to some embodiments of the present disclosure;

FIG. 2 is a schematic structural diagram of a display panel according to some embodiments of the present disclosure;

FIG. 3 is a schematic structural diagram of a display panel according to some embodiments of the present disclosure;

FIG. 4 is a schematic structural diagram of a display panel according to some embodiments of the present disclosure;

FIG. 5 is a schematic structural diagram of a display panel according to some embodiments of the present disclosure;

FIG. 6 is a schematic structural diagram of a display panel according to some embodiments of the present disclosure;

FIG. 7 is a schematic structural diagram of a first through hole formed according to some embodiments of the present disclosure;

FIG. 8 is a schematic structural diagram of a second through hole and a third through hole formed according to some embodiments of the present disclosure;

FIG. 9 is a schematic structural diagram of a second through hole and a third through hole formed according to some embodiments of the present disclosure;

FIG. 10 is a schematic structural diagram of a second through hole and a third through hole formed according to some embodiments of the present disclosure;

FIG. 11 is a schematic structural diagram of a second through hole and a third through hole formed according to some embodiments of the present disclosure;

FIG. 12 is a schematic structural diagram of a second through hole, a first through sub-hole, and a second through sub-hole formed according to some embodiments of the present disclosure;

FIG. 13 is a schematic structural diagram of forming a second through hole, a first through sub-hole, and a second through sub-hole formed according to some embodiments of the present disclosure;

FIG. 14 is a schematic flowchart of a method for manufacturing a display panel according to some embodiments of the present disclosure.

The reference numbers of the main components in the drawings are explained as follows:

110—Hard base substrate; 120—First flexible layer; 130—Buffer layer; 140—Second flexible layer; 141—First through hole; 150—Inorganic layer; 151—Second through hole; 51H—Second hole wall; 10—Signal line; 210—Active layer; 220—Insulation layer; 221—First gate insulation layer; 2211—First through sub-hole; 11H—First sub-hole wall; 222—Second gate insulation layer; 2221—Second through sub-hole; 21H—Second sub-hole wall; 2200—Third through hole; 00H—Third hole wall; 230—First conductive layer; 231—Adapter line; 240—Second conductive layer; ILD—Interlayer dielectric layer; 250—Third conductive layer; PVX—Passivation layer; PLN1—First planarization layer; 260—Fourth conductive layer; PLN2—Second planarization layer; 310—Pixel definition layer; 320—First electrode; 330—Light emitting functional layer; 400—Spacer.

### DETAILED DESCRIPTION

Example embodiments will now be described more fully with reference to the accompanying drawings. Example embodiments may, however, be embodied in many forms and should not be construed as limited to the examples set forth here; rather, these embodiments are provided so that the present disclosure will be thorough and complete, and will fully convey the concept of example embodiments to those skilled in the art. The described features, structures, or characteristics may be combined in any suitable manner in one or more embodiments. In the following description, numerous specific details are provided in order to give a thorough understanding of embodiments of the present disclosure.

In the drawings, thicknesses of regions and layers may be exaggerated for clarity. The same reference numbers in the drawings denote the same or similar structures, and thus their detailed descriptions will be omitted.

The described features, structures, or characteristics may be combined in any suitable manner in one or more embodiments. In the following description, numerous specific details are provided in order to give a thorough understanding of embodiments of the present disclosure. However, those skilled in the art will appreciate that the technical solutions of the present disclosure may be practiced without one or more of the specific details, or that other methods, components, materials, etc. may be employed. In other instances, well-known structures, materials, or operations are not shown or described in detail to avoid obscuring the main technical idea of the present disclosure.

When a structure is “on” another structure, it may mean that a structure is integrally formed on another structure, or that a structure is “directly” placed on another structure, or that a structure is “indirectly” placed on another structure through another structure.

The terms “a”, “an” and “the” are used to indicate the presence of one or more elements/components/etc. The terms “include” and “comprise” are used to express the meaning of open inclusion and refer to the existence of other elements/components/etc. in addition to the listed elements/components/etc. The terms “first” and “second” are used only as marks, not as a quantitative limit on their objects.

The lower frame of the display screen is affected by the wiring of the fan-shaped region (Fanout), and the width of the lower frame is usually wider than the width of the left and right frames. In the related art, the lower frame of the display screen can be reduced by redesigning the wiring, but this method still needs to be perfected. For example, the signal line is provided with two flexible layers of polyimide (Polyimide, PI) layers, such as between the first flexible layer and the second flexible layer; an adapter hole is provided in the driving circuit layer above the two flexible layers, the adapter hole exposes the signal line, and an adapter metal layer is formed in the adapter hole to transmit the power supply voltage. However, in this solution, the adapter metal layer formed in the adapter hole is usually in direct contact with the second flexible layer, and external water vapor will enter along the second flexible layer, affecting the reliability of the display screen.

The purpose of the present disclosure is to provide a display panel, a method for manufacturing a display panel, and a display device. While reducing the frame of the display panel, it facilitates to block the entry of external water vapor, avoiding corrosion to the devices inside the display panel, so as to ensure the reliability of the display panel.

In order to achieve the above-mentioned purpose, the present disclosure adopts the following technical solutions.

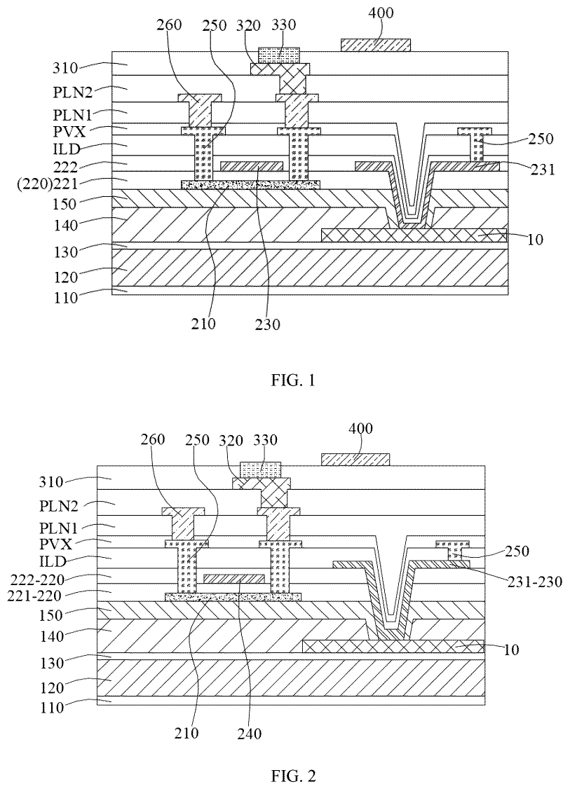

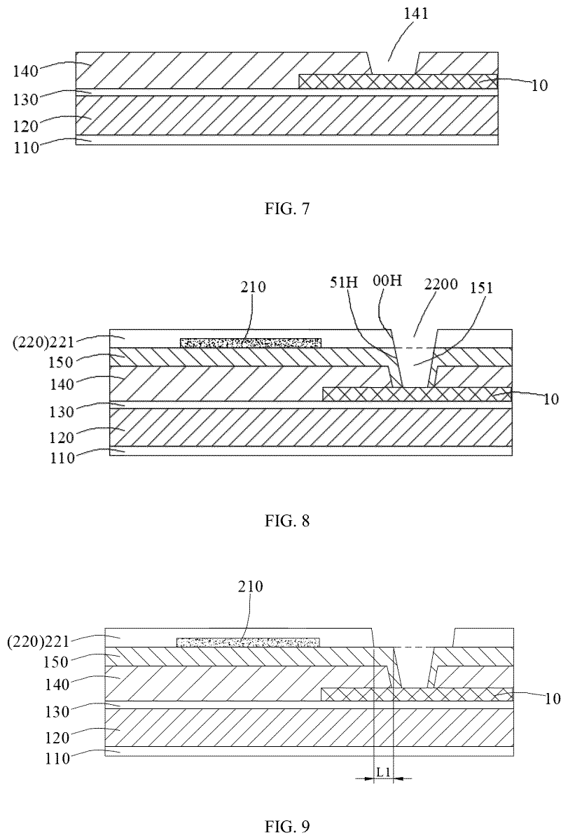

As shown in FIG. 1, FIG. 7 and FIG. 8, according to embodiments of the present disclosure, there is provided a display panel, including a first flexible layer 120, a signal line 10, a second flexible layer 140, an inorganic layer 150 and a first conductive layer 230. Among them, the second flexible layer 140 is provided on a side of the first flexible layer 120; the signal line 10 is provided between the first flexible layer 120 and the second flexible layer 140; the second flexible layer 140 is provided with a first through hole 141, and the first through hole 141 exposes the surface of the signal line 10 away from the first flexible layer 120; the inorganic layer 150 covers the surface of the second flexible layer 140 away from the first flexible layer 120 and the sidewall of the first through hole 141; the inorganic layer 150 is provided with a second through hole 151; the orthographic projection of the second through hole 151 on the first flexible layer 120 is located within the orthographic projection of the first through hole 141 on the first flexible layer 120, and the second through hole 151 exposes the surface of the signal line 10 away from the first flexible layer 120; the first conductive layer 230 includes an adapter line 231, and the adapter line 231 at least covers the sidewall of the second through hole 151 and the surface of the signal line 10 exposed by the second through hole 151.

In the display panel provided by the present disclosure, the signal line 10 is provided between the first flexible layer 120 and the second flexible layer 140, which helps to reduce the width of the lower frame of the display panel. In addition, the inorganic layer 150 covers the surface of the second flexible layer 140 away from the first flexible layer 120 and the sidewall of the first through hole 141, that is, wraps the second flexible layer 140. While reducing the frame of the display panel, this structural design helps to block the entry of external water vapor and avoids corrosion to the devices in the display panel, so as to ensure the reliability of the display panel.

The components of the display panel provided by the embodiments of the present disclosure will be described in detail below in conjunction with the accompanying drawings.

The present disclosure provides a display panel, which may be an organic light-emitting diode (OLED) display panel, such as an AMOLED (Active-matrix organic light-emitting diode) display panel. It may also be a quantum dot light emitting diode (QLED) display panel, a micro light emitting diode (Micro LED) display panel, etc., which is not specifically limited in the present disclosure.

As shown in FIG. 1 to FIG. 6, FIG. 7 and FIG. 8, the display panel includes a first flexible layer 120, a signal line 10, a second flexible layer 140, an inorganic layer 150 and a first conductive layer 230.

The first flexible layer 120, the second flexible layer 140 and the inorganic layer 150 may form a base substrate of the display panel, and the second flexible layer 140 is provided on a side of the first flexible layer 120. The material of the first flexible layer 120 and the second flexible layer 140 may include polyimide (PI).

In some embodiments of the present disclosure, the display panel further includes a buffer layer 130 provided between the first flexible layer 120 and the second flexible layer 140. The material of the buffer layer 130 may include an inorganic material, and the buffer layer 130 may play a good adhesion between the flexible layer 120 and the second flexible layer 140.

The signal line 10 is provided between the first flexible layer 120 and the second flexible layer 140. The signal line 10 may be provided on the side of the buffer layer 130 close to the first flexible layer 120, or provided on the side of the buffer layer 130 away from the first flexible layer 120, which is not limited in the present disclosure. In some embodiments, the signal line 10 is provided on a side of the buffer layer 130 away from the first flexible layer 120. The second flexible layer 140 is provided with a first through hole 141, and the first through hole 141 exposes a surface of the signal line 10 away from the first flexible layer 120.

The inorganic layer 150 covers the surface of the second flexible layer 140 away from the first flexible layer 120 and the sidewall of the first through hole 141, and specifically contacts the sidewall of the second flexible layer 140 at the position of the first through hole 141, so that the second flexible layer 140 is wrapped to prevent external water vapor from entering the position of the first through hole 141 along the second flexible layer 140.

The inorganic layer 150 is provided with a second through hole 151, the orthographic projection of the second through hole 151 on the first flexible layer 120 is located within the orthographic projection of the first through hole 141 on the first flexible layer 120, and the second through hole 151 exposes the surface of the signal line 10 away from the first flexible layer 120. That is, the second through hole 151 communicates with the first through hole 141 to expose the surface of the signal line 10 away from the first flexible layer 120.

The first conductive layer 230 includes an adapter line 231 connected to the signal line 10, and the adapter line 231 at least covers the sidewall of the second through hole 151 and the surface of the signal line 10 exposed by the second through hole 151. The first conductive layer 230 may include metal material or alloy material to ensure its good electrical conductivity. The first conductive layer 230 may also be made of transparent conductive materials, such as ITO (indium tin oxide), IZO (indium zinc oxide), and the like. In the present disclosure, the adapter line 231 and the second flexible layer 140 is blocked by the inorganic layer 150. This structure helps to prevent external water vapor from penetrating into the adapter line 231 along the second flexible layer 140, and prevents corrosion to the devices such as the adapter line 231.

As shown in FIG. 8 to FIG. 13, in some embodiments of the present disclosure, the display panel further includes an insulation layer 220 provided on a side of the inorganic layer 150 away from the first flexible layer 120. The insulation layer 220 can be a single film layer such as silicon nitride, silicon oxide, aluminum oxide, etc., or a multi-film layer formed by a combination of them. The insulation layer 220 is provided with a third through hole 2200, the third through hole 2200 communicates with the second through hole 151, and the orthographic projection of the second through hole 151 on the first flexible layer 120 is located within the orthographic projection of the third through hole 2200 on the flexible layer 120. In some embodiments, the surface of the signal line 10 away from the first flexible layer 120 is exposed by the second through hole 151 and the third through hole 2200. The diameter of the second through hole 151 is smaller than or equal to the diameter of the third through hole 2200. The total penetration depth of the third through hole 2200 and the second through hole 151 may be 5-8 μm.

The second through hole 151 has a second hole wall 51H, and the third through hole 2200 has a third hole wall 00H. In some embodiments of the present disclosure, the second hole wall 51H and the third hole wall 00H are connected to each other to form a through hole wall, and the through hole wall has at least one stepped portion, and the stepped portion can buffer the adapter line 231 to avoid its breaking.

In some embodiments of the present disclosure, a first distance L1 parallel to the direction of the first flexible layer 120 is provided between an end of the second hole wall 51H away from the first flexible layer 120 and an end of the third hole wall 00H close to the first flexible layer 120. The first distance L1 is greater than or equal to zero. As shown in FIG. 1 to FIG. 6, the adapter line 231 covers at least part of the surface of the insulation layer 220 away from the first flexible layer 120, and at least covers t the second hole wall 51H and the third hole wall 00H.

Continuously as shown in FIG. 8 to FIG. 13, the end of the second hole wall 51H away from the first flexible layer 120 is the boundary line between the surface of the inorganic layer 150 away from the first flexible layer 120 and the edge of the second through hole 151. The end of the third hole wall 00H close to the first flexible layer 120 is the boundary line between the surface of the insulation layer 220 close to the first flexible layer 120 and the edge of the third through hole 2200. Among them, the surface of the insulation layer 220 close to the first flexible layer 120 is in contact with the surface of the inorganic layer 150 away from the first flexible layer 120. At this time, the adapter line 231 located in the third through hole 2200 and the second through hole 151 covers the third hole wall 00H, the second hole wall 51H and the surface of the signal line 10 exposed by the second through hole 151.

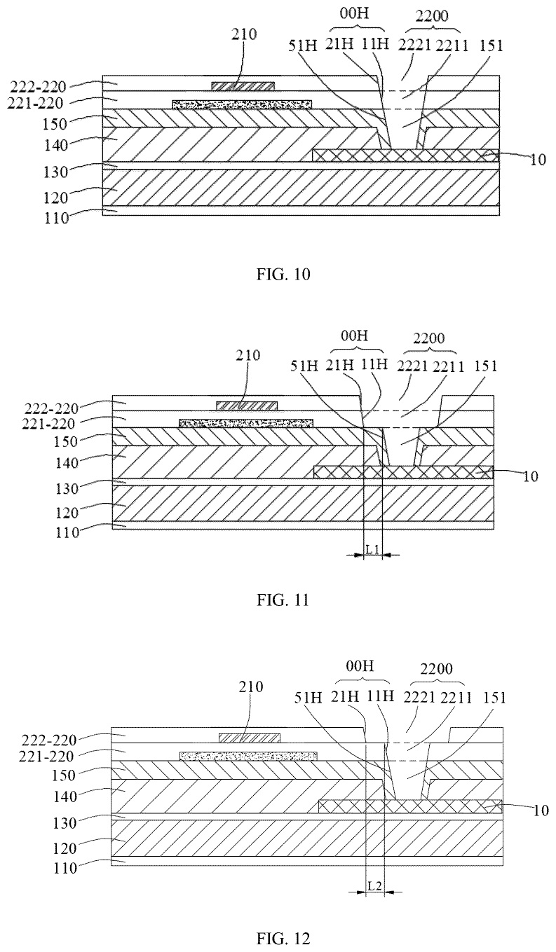

As shown in FIG. 8, FIG. 10 and FIG. 12, in some embodiments of the present disclosure, the first distance L1 is approximately equal to 0, and the end of the second hole wall 51H away from the first flexible layer 120 coincides with the end of the third hole wall 00H close to the first flexible layer 120, and the second hole wall 51H and the third hole wall 00H are roughly connected to form a smooth sidewall.

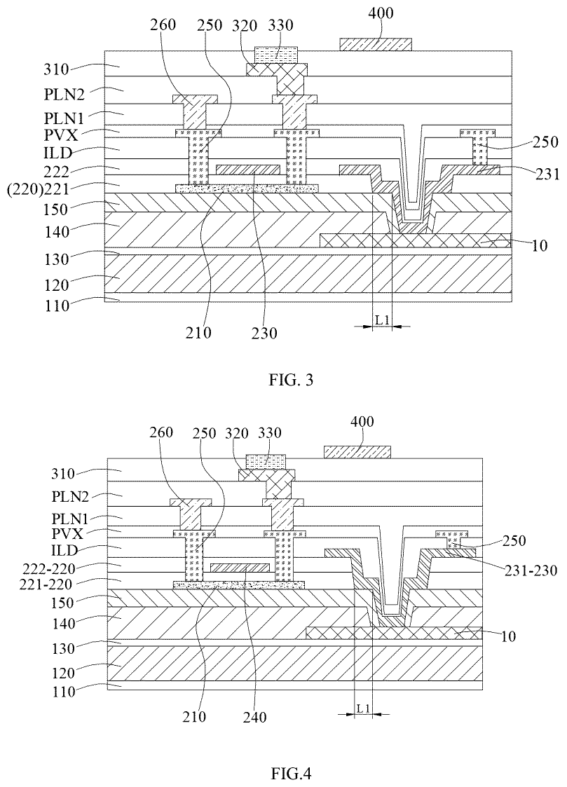

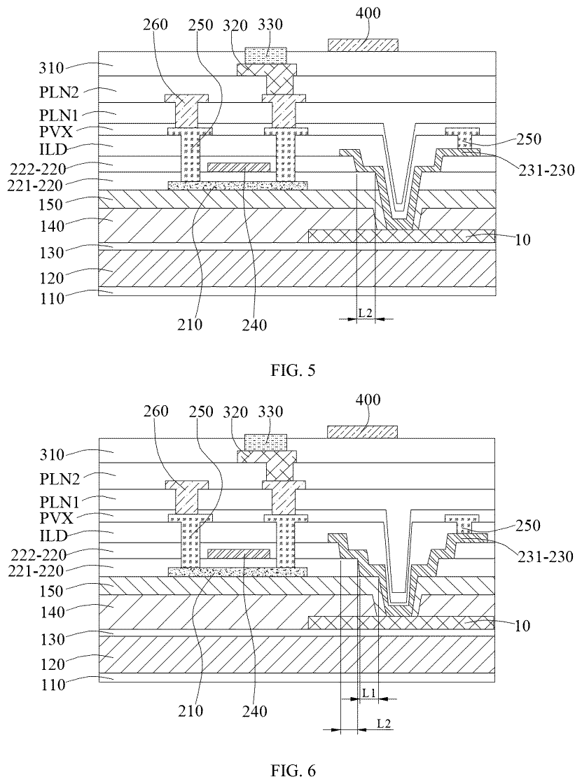

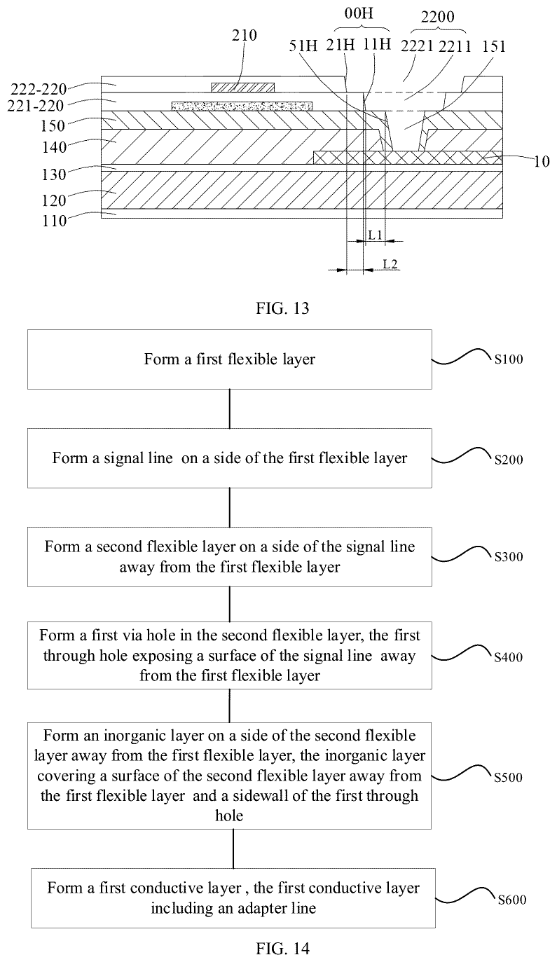

As shown in FIG. 9, FIG. 11 and FIG. 13, in other embodiments of the present disclosure, the first distance L1 is greater than 0, and the end of the second hole wall 51H away from the first flexible layer 120 does not coincide with the end of the third hole wall 00H close to the first flexible layer 120. The third hole wall 00H, the surface of the inorganic layer 150 away from the first flexible layer 120 and the second hole wall 51H can be connected to form at least one stepped portion. As shown in FIG. 3, FIG. 4 and FIG. 6, at this time, the adapter line 231 located in the third through hole 2200 and the second through hole 151 covers the third hole wall 00H, a part of the surface of the inorganic layer 150 away from the first flexible layer 120, that is, the surface of the inorganic layer 150 corresponding to the first distance L1, the second hole wall 51H, and the surface of the signal line 10 exposed by the second through hole 151. In some embodiments, the adapter line 231 located in the third through hole 2200 and the second through hole 151 is less likely to be broken during fabrication due to the buffer of the stepped portion.

In some embodiments, the first distance L1 is not less than 3 μm. In some embodiments, it may be 3 μm, 3.1 μm, 3.2 μm, 3.3 μm, 3.4 μm, 3.5 μm, 3.6 μm, 3.7 μm, 3.8 μm, 3.9 μm or 4 μm, but not limited to this. In practical applications, it can be set according to needs.

As shown in FIG. 1 to FIG. 6, in some embodiments of the present disclosure, the display panel further includes an active layer 210 provided between the inorganic layer 150 and the insulation layer 220. The material of the active layer 210 can be polysilicon or IGZO (Indium Gallium Zinc Oxide), which can change the conductivity at different positions through processes such as doping. The insulation layer 220 may include a single-layer, two-layer or multi-layer structure, which may be specifically set according to actual conditions. The different disposition manners of the insulation layer 220 of the present disclosure will be described in detail below in combination with specific embodiments.

As shown in FIG. 1, FIG. 3, FIG. 8 and FIG. 9, in some embodiments of the present disclosure, the insulation layer 220 includes a first gate insulation layer 221, and the first gate insulation layer 221 is provided with a third through hole 2200. The first gate insulation layer 221 is located between the active layer 210 and the first conductive layer 230. The first conductive layer 230 also includes a gate of the transistor and a first plate of the capacitor. The adapter line 231 covers at least part of the surface of the first gate insulation layer 221 away from the first flexible layer 120. In some embodiments, the adapter line 231 covers the third hole wall 00H, which is the sidewall of the first gate insulation layer 221 at the position of the third through hole 2200.

In some embodiments, the display panel further includes a second gate insulation layer 222, a second conductive layer (not shown in the drawing), an interlayer dielectric layer ILD and a third conductive layer 250. Among them, the second gate insulation layer 222 is provided on the side of the first conductive layer 230 away from the first flexible layer 120, and the second gate insulation layer 222 covers the surfaces of the first conductive layer 230 and the first gate insulation layer 221. The second conductive layer is provided on the surface of the second gate insulation layer 222 away from the first flexible layer 120, and the second conductive layer includes a second plate of the capacitor. The interlayer dielectric layer ILD is provided on a side of the second conductive layer away from the first flexible layer 120, and the interlayer dielectric layer ILD covers the second conductive layer and the second gate insulation layer 222. The third conductive layer 250 is provided on the side of the interlayer dielectric layer ILD away from the first flexible layer 120, the third conductive layer 250 includes the source and the drain of the transistor, and the source and the drain are connected to the active layer 210; the third conductive layer 250 is connected to the adapter line 231, and further connected to the signal line 10, which can be used to provide a power supply voltage signal to the pixel circuit, so as to apply the power supply voltage signal to the source or drain of the transistor.

As shown in FIG. 2, FIG. 4 to FIG. 6, and FIG. 10 to FIG. 13, in other embodiments of the present disclosure, the insulation layer 220 includes a first gate insulation layer 221 and a second gate insulation layer 221 provided in sequence along a direction away from the first flexible layer 120. The first gate insulation layer 221 and the second gate insulation layer 222 are provided with a third through hole 2200. The first gate insulation layer 221 covers the active layer 210. The first conductive layer 230 includes the second plate of the capacitor. The first conductive layer 230 is provided on a side of the second gate insulation layer 222 away from the first flexible layer 120, and the adapter line 231 covers at least part of the surface of the second gate insulation layer 222 away from the first flexible layer 120. In some embodiments, the adapter line 231 covers the third hole wall 00H, which is the sidewall of the first gate insulation layer 221 and the second gate insulation layer 222 at the position of the third through hole 2200.

The display panel further includes a second conductive layer 240, an interlayer dielectric layer ILD and a third conductive layer 250. Among them, the second conductive layer 240 is provided between the first gate insulation layer 221 and the second gate insulation layer 222, and the second gate insulation layer 222 covers the second conductive layer 240 and the first gate insulation layer 221. The second conductive layer 240 includes the gate of the transistor and the first plate of the capacitor. The interlayer dielectric layer ILD is provided on a side of the first conductive layer 230 away from the first flexible layer 120, and the interlayer dielectric layer ILD covers the first conductive layer 230 and the second gate insulation layer 222. The third conductive layer 250 is provided on the side of the interlayer dielectric layer ILD away from the first flexible layer 120, the third conductive layer 250 includes the source and the drain of the transistor, and the source and the drain are connected to the active layer 210; and the third conductive layers 250 are connected to the adapter line 231, and further connected to the signal line 10, which can be used to provide a power supply voltage signal to the pixel circuit, so as to apply the power supply voltage signal to the source or drain of the transistor.

As shown in FIG. 10, FIG. 11, FIG. 12 and FIG. 13, in some embodiments, the third through hole 2200 includes a first through sub-hole 2211 and a second through sub-hole 2221. The first gate insulation layer 221 is provided with the first through sub-hole 2211, and the second gate insulation layer 222 is provided with the second through sub-hole 2221. The orthographic projection of the first through sub-hole 2211 on the first flexible layer 120 is located within the orthographic projection of the second through sub-hole 2221 on the first flexible layer 120. The first through sub-hole 2211 has a first sub-hole wall 11H, the second through sub-hole 2221 has a second sub-hole wall 21H. A second distance L2 parallel to the direction of the first flexible layer 120 is provided between the end of the first sub-hole wall 11H far away from the first flexible layer 120 and the end of the second sub-hole wall 21H close to the first flexible layer 120, and the second distance L2 is greater than or equal to zero.

In some embodiments, the end of the first sub-hole wall 11H away from the first flexible layer 120 is the boundary line between the surface of the first gate insulation layer 221 away from the first flexible layer 120 and the edge of the first through sub-hole 2211. The end of the sub-hole wall 21H close to the first flexible layer 120 is the boundary line between the surface of the second gate insulation layer 222 close to the first flexible layer 120 and the edge of the second through sub-hole 2221, where the surface of the first gate insulation layer 221 far away from the first the flexible layer 120 is in contact with the surface of the second gate insulation layer 222 close to the first flexible layer 120. At this time, the adapter line 231 located in the third through hole 2200 and the second through hole 151 covers the second sub-hole wall 21H, the first sub-hole wall 11H, the second hole wall 51H and the surface of the signal line 10 exposed by the second through hole 151.

As shown in FIG. 10 and FIG. 11, in some embodiments of the present disclosure, the second distance L2 is approximately equal to 0, and the end of the first sub-hole wall 11H away from the first flexible layer 120 coincides with the end of the second sub-hole wall 21H close to the first flexible layer 120. The first sub-hole wall 11H and the second sub-hole wall 21H are roughly connected to form a smooth sidewall.

As shown in FIG. 12 and FIG. 13, in other embodiments of the present disclosure, the second distance L2 is greater than 0, and the end of the first sub-hole wall 11H away from the first flexible layer 120 does not coincides with the second sub-hole wall 21H close to the first flexible layer 120. The first sub-hole wall 11H, the surface of the first gate insulation layer 221 away from the first flexible layer 120 and the second sub-hole wall 21H can be connected to form at least one stepped portion. At this time, as shown in FIG. 5 and FIG. 6, the adapter line 231 located in the first through sub-hole 2211 and the second through sub-hole 2221 covers the second sub-hole wall 21H, a part of the surface of the first gate insulation layer 221 away from the first flexible layer 120 and the first sub-hole wall 11H. In some embodiments, the first sub-hole wall 11H and the second sub-hole wall 21H form a stepped portion, which can further buffer the formation of the adapter line 231 and help to further reduce the possibility of breaking of the adapter line 231 in the through hole due to the depth of the through hole too large.

In some embodiments, the second distance L2 is not less than 3 μm. In some embodiments, it may be 3 μm, 3.1 μm, 3.2 μm, 3.3 μm, 3.4 μm, 3.5 μm, 3.6 μm, 3.7 μm, 3.8 μm, 3.9 μm or 4 μm, but not limited to this. In practical applications, it can be set according to needs.

As shown in FIG. 1 to FIG. 6, in some embodiments of the present disclosure, the display panel further includes a passivation layer PVX, a first planarization layer PLN1, a fourth conductive layer 260 and a second planarization layer PLN2. Among them, the passivation layer PVX is provided on the side of the third conductive layer 250 away from the first flexible layer 120, and the passivation layer PVX covers the third conductive layer 250 and the interlayer dielectric layer ILD. The first planarization layer PLN1 is provided on a side of the passivation layer PVX away from the first flexible layer 120, and first planarization layer PLN1 covers the passivation layer PVX. The fourth conductive layer 260 is provided on the side of the first planarization layer PLN1 away from the first flexible layer 120, and the fourth conductive layer 260 is connected to the third conductive layer 250 through a via hole.

The display panel further includes a second planarization layer PLN2, a light emitting layer and a spacer 400. The second planarization layer PLN2 is provided on the side of the fourth conductive layer 260 away from the first flexible layer 120, and the second planarization layer PLN2 covers the fourth conductive layers 260 and the first planarization layer PLN1. The light emitting layer is provided on the side of the second planarization layer PLN2 away from the first flexible layer 120. The light emitting layer includes a pixel definition layer 310 and a plurality of light emitting devices. The spacer 400 is provided on the side of the pixel definition layer 310 away from the first flexible layer 120.

The pixel definition layer 310 is provided on the side of the second planarization layer PLN2 away from the first flexible layer 120. The pixel definition layer 310 may be provided with a plurality of openings, and the range defined by each opening is the range of a light emitting device. The shape of the opening, that is, the shape of the contour of the orthographic projection of the opening on the first flexible layer 120, may be a polygon, a smooth closed curve or other shapes, which are not specifically limited here.

The light emitting device can be connected with the fourth conductive layer 260 and can emit light under the drive of the driving circuit. Taking the light emitting device being an OLED light emitting device as an example, the light emitting device may include a first electrode 320, a light emitting functional layer 330 and a second electrode stacked in sequence along a direction away from the first flexible layer 120. The first electrode 320 may be an anode, and the second electrode may be a cathode. The structure of the light emitting device is a conventional structure in the field, and will not be described in detail here.

As shown in FIG. 1 to FIG. 6 and FIG. 14, the present disclosure also provides a method for manufacturing a display panel, including the following.

In step S100, a first flexible layer 120 is formed.

In step S200, a signal line 10 is formed on a side of the first flexible layer 120.

In step S300, a second flexible layer 140 is formed on a side of the signal line 10 away from the first flexible layer 120.

In step S400, a first through hole 141 is formed in the second flexible layer 140, where the first through hole 141 exposes the surface of the signal line 10 away from the first flexible layer 120.

In step S500, an inorganic layer 150 is formed on a side of the second flexible layer 140 away from the first flexible layer 120, where the inorganic layer 150 covers the surface of the second flexible layer 140 away from the first flexible layer 120 and the sidewall of the first through hole 141.

In step S600, the first conductive layer 230 is formed, where the first conductive layer 230 includes the adapter line 231.

Among them, the second through hole 151 is formed in the inorganic layer 150, the orthographic projection of the second through hole 151 on the first flexible layer 120 is located within the orthographic projection of the first through hole 141 on the first flexible layer 120, and the second through hole 151 exposes the surface of the signal line 10 away from the first flexible layer 120; the adapter line 231 at least covers the sidewall of the second through hole 151 and the surface of the signal line 10 exposed by the second through hole 151.

In the method for manufacturing the display panel provided by present disclosure, the first through hole 141 is formed in the second flexible layer 140, and then the inorganic layer 150 is formed, so that the formed inorganic layer 150 can wrap up the second flexible layer 140 at the position of the first through hole 141, so that the inorganic layer 150 is used to block the entry of external water vapor, and avoid corrosion to the devices in the display panel.

In some embodiments of the present disclosure, before step S100, it may further include providing a hard base substrate 110, and the material of the hard base substrate 110 may be glass or the like. In step S100, the first flexible layer 120 may be formed on a side of the hard base substrate 110.

As shown in FIG. 8 to FIG. 13, in some embodiments of the present disclosure, before step S600, it further includes the following.

In step S501, an insulation layer 220 is formed on the side of the inorganic layer 150 away from the first flexible layer 120.

A third through hole 2200 is formed in the insulation layer 220, the insulation layer 220 covers at least part of the surface of the inorganic layer 150, and the third through hole 2200 communicates with the second through hole 151. The orthographic projection of the second through hole 151 on the first flexible layer 120 is located within the orthographic projection of the third through hole 2200 on the first flexible layer 120. The second through hole 151 has a second hole wall 51H, the third through hole 2200 has a third hole wall 00H. A first distance L1 parallel to the direction of the first flexible layer 120 is provided between the end of the second hole wall 51H away from the first flexible layer 120 and the end of the third hole wall 00H close to the first flexible layer 120, and the first distance L1 is greater than or equal to zero. The adapter line 231 covers at least part of the surface of the insulation layer 220 away from the first flexible layer 120, and at least covers the second hole wall 51H and the third hole wall 00H.

In step S501, the insulation layer 220 formed may include a single-layer or multi-layer structure. The following will describe in detail in conjunction with different embodiments.

As shown in FIG. 8 and FIG. 9, in an embodiment of the present disclosure, step S501 includes the following.

A first gate insulation layer 221 is formed on the side of the inorganic layer 150 away from the first flexible layer 120, and the first gate insulation layer 221 covers at least part of the surface of the inorganic layer 150 away from the first flexible layer 120.

In some embodiments, the third through hole 2200 is formed in the first gate insulation layer 221; the adapter line 231 covers at least part of the surface of the first gate insulation layer 221 away from the first flexible layer 120.

In some embodiments, the third through hole 2200 in the first gate insulation layer 221 and the second through hole 151 in the inorganic layer 150 can be formed by one etching process, or can be formed by multiple etching processes.

In some embodiments, when the first distance L1 is approximately equal to 0, the third through hole 2200 and the second through hole 151 can be formed by one etching process. For example, as shown in FIG. 8, after the first gate insulation layer 221 is formed, an etching process is used to etch the first gate insulation layer 221 and the inorganic layer 150 at the same time, so as to form the third three through holes 2200 in the first gate insulation layer 221 and the second through hole 151 in the inorganic layer 150. In the embodiment, after step S600 is performed to form the first conductive layer 230, a display panel as shown in FIG. 1 can be formed. For the structure of the display panel, reference may be made to the description in the above embodiments, and details are not repeated here.

When the first distance L1 is greater than 0, the third through hole 2200 and the second through hole 151 are formed using different etching processes. For example, as shown in FIG. 9, after forming the first gate insulation layer 221, a first etching process can be used to form the third through hole 2200 in the first gate insulation layer 221, and then a second etching process can be used to form the second through hole 151 in the inorganic layer 150. The diameter of the second through hole 151 may be smaller than the diameter of the third through hole 2200. In the embodiment, after step S600 is performed to form the first conductive layer 230, the display panel as shown in FIG. 3 can be formed. For the structure of the display panel, reference may be made to the descriptions in the above embodiments, and details are not repeated here.

As shown in FIG. 10 to FIG. 13, in another embodiment of the present disclosure, step S501 includes the following.

In step S5011, a first gate insulation layer 221 is formed on the side of the inorganic layer 150 away from the first flexible layer 120, the first gate insulation layer 221 covers at least part of the surface of the inorganic layer 150 away from the first flexible layer 120.

In step S5012, a second gate insulation layer 222 is formed on the side of the first gate insulation layer 221 away from the first flexible layer 120, the second gate insulation layer 222 covers at least part of the surface of the first gate insulation layer 221 away from the first flexible layer 120.

In some embodiments, the third through hole 2200 is provided in the first gate insulation layer 221 and the second gate insulation layer 222; the adapter line 231 covers at least part of the surface of the second gate insulation layer 222 away from the first flexible layer 120.

In some embodiments, the third through hole 2200 in the first gate insulation layer 221 and the second gate insulation layer 222 and the second through hole 151 in the inorganic layer 150 can be formed by one etching process, or by separate etching process.

In some embodiments, when the first distance L1 is approximately equal to 0, the third through hole 2200 and the second through hole 151 can be formed by one etching process. For example, as shown in FIG. 10, after the second gate insulation layer 222 is formed, an etching process is used to etch the second gate insulation layer 222, the first gate insulation layer 221 and the inorganic layer 150 at the same time, so that the third through hole 2200 is formed in the gate insulation layer 222 and the first gate insulation layer 221 and the second through hole 151 is formed in the inorganic layer 150. In the embodiment, after step S600 is performed to form the first conductive layer 230, the display panel as shown in FIG. 2 can be formed. For the structure of the display panel, reference may be made to the descriptions in the above embodiments, and details are not repeated here.

When the first distance L1 is greater than 0, the third through hole 2200 and the second through hole 151 are formed using different etching processes. For example, as shown in FIG. 11, after forming the second gate insulation layer 222, a third through hole 2200 can be formed in the second gate insulation layer 222 and the first gate insulation layer 221 by one etching process, and then another etching process is used to form the second through hole 151 in the inorganic layer 150. The diameter of the second through hole 151 may be smaller than the diameter of the third through hole 2200. In the embodiment, after step S600 is performed to form the first conductive layer 230, the display panel as shown in FIG. 4 can be formed. For the structure of the display panel, reference may be made to the descriptions in the above embodiments, and details are not repeated here.

In some embodiments of the present disclosure, a first through sub-hole 2211 is formed in the first gate insulation layer 221, a second through sub-hole 2221 is formed in the second gate insulation layer 222, and the first through sub-hole 2211 and the second through sub-hole 2221 forms the third through hole 2200; the orthographic projection of the second through hole 151 on the first flexible layer 120 is located within the orthographic projection of the first through sub-hole 2211 on the first flexible layer 120, and the orthographic projection of the first through sub-hole 2211 on the first flexible layer 120 is located within the orthographic projection of the second through sub-hole 2221 on the first flexible layer 120; the first through sub-hole 2211 has a first sub-hole wall 11H, and the second through sub-hole 2221 has a second sub-hole wall 21H. A second distance L2 parallel to the direction of the first flexible layer 120 is provided between the end of the first sub-hole wall 11H away from the first flexible layer 120 and the end of the second sub-hole wall 21H close to the first flexible layer 120. The second distance L2 is greater than or equal to zero.

In some embodiments, the first through sub-hole 2211 in the first gate insulation layer 221 and the second through sub-hole 2221 in the second gate insulation layer 222 can be formed by one etching process, or can be formed by separate etching processes.

In some embodiments, when the second distance L2 is equal to 0, the first through sub-hole 2211 and the second through sub-hole 2221 can be formed by one etching process, specifically, a structure as shown in FIG. 10 or FIG. 11 can be formed. It should be noted here that when the first distance L1 is equal to 0 too, the second through sub-hole 2221, the first through sub-hole 2211 and the second through hole 151 can be formed by one etching process, specifically, a structure as shown in FIG. 10 can be formed.

When the second distance L2 is greater than 0, the first through sub-hole 2211 and the second through sub-hole 2221 can be formed by two etching processes, specifically, a structure as shown in FIG. 12 or FIG. 13 can be formed. For example, as shown in FIG. 13, when the first distance L1 is greater than 0 too, after forming the second gate insulation layer 222, the second through sub-hole 2221 can be formed in the second gate insulation layer 222 by one etching process, another etching process can be used to form the first through sub-hole 2211 in the first gate insulation layer 221. The diameter of the first through sub-hole 2211 is smaller than the diameter of the second through sub-hole 2221. And then, another etching process is used to form the second through hole 151 in the inorganic layer 150. The diameter of the second through hole 151 is smaller than the diameter of the first through sub-hole 2211. In the embodiment, after step S600 is performed to form the first conductive layer 230, a display panel as shown in FIG. 6 can be formed. For the structure of the display panel, reference may be made to the description in the above embodiments, and details are not repeated here.

As shown in FIG. 12, when the first distance L1 is equal to 0, the first through sub-hole 2211 and the second through hole 151 can be formed by one etching process. In some embodiments, after the second gate insulation layer 222 is formed, the second through sub-hole 2221 can be formed in the second gate insulation layer 222 by one etching process, and another etching process can be used to etch the first gate insulation layer 221 and the inorganic layer 150 at the same time, so as to form the first through sub-hole 2211 in the first gate insulation layer 221 and form the second through hole 151 in the inorganic layer 150. specifically, a structure as shown in FIG. 12 can be formed. In the embodiment, after step S600 is performed to form the first conductive layer 230, the display panel as shown in FIG. 5 can be formed. For the structure of the display panel, reference may be made to the descriptions in the above embodiments, and details are not repeated here.

In some embodiments of the present disclosure, neither the first distance L1 nor the second distance L2 is less than 3 μm. In some embodiments, it may be 3 μm, 3.1 μm, 3.2 μm, 3.3 μm, 3.4 μm, 3.5 μm, 3.6 μm, 3.7 μm, 3.8 μm, 3.9 μm or 4 μm, but not limited to this. In practical applications, it can be set according to needs.

As shown in FIG. 1 to FIG. 6, in some embodiments of the present disclosure, the method for manufacturing the display panel further includes the following.

In step S700, an interlayer dielectric layer ILD, a third conductive layer 250, a passivation layer PVX, a first planarization layer PLN1, a fourth conductive layer 260, a second planarization layer PLN2 and a light emitting layer, etc., are formed on the side of the first conductive layer 230 away from the first flexible layer 120 in sequence. This step can specifically adopt conventional methods in the art, which will not be described in detail here.

Embodiments of the present disclosure also provide a display device, including a display panel. The display panel may be the display panel in any of the above embodiments. For its specific structure and beneficial effects, reference can be made to the above embodiments of the display panel, which will not be repeated here. The display device of the present disclosure may be an electronic equipment such as a mobile phone, a tablet computer, and a television, which will not be listed here.

It should be noted that although the steps of the method in the present disclosure are described in a specific order in the drawings, this does not require or imply that these steps must be performed in the specific order, or that all the steps shown must be performed to more than one step can be combined into one step for execution, and/or one step can be decomposed into multiple steps for execution, which should be considered as a part of the present disclosure.

It is understandable that the present disclosure does not limit its application to the detailed structure and arrangement of the components proposed in this specification. The present disclosure can have other embodiments, and can be implemented and implemented in a variety of ways. The present disclosure disclosed and limited by the description extends to all alternative combinations of two or more individual features mentioned or apparent in the text and/or the drawings. All these different combinations constitute a plurality of alternative aspects of the present disclosure. The embodiments of the description describe the best known methods for realizing the present disclosure, and will enable those skilled in the art to take advantage of the present disclosure.

1. A display panel, comprising:
a first flexible layer;
a second flexible layer, provided on a side of the first flexible layer;
a signal line, provided between the first flexible layer and the second flexible layer, wherein the second flexible layer is provided with a first through hole, and the first through hole exposes a surface of the signal line away from the first flexible layer;
an inorganic layer, covering a surface of the second flexible layer away from the first flexible layer and a sidewall of the first through hole, wherein the inorganic layer is provided with a second through hole, an orthographic projection of the second through hole on the first flexible layer is located within an orthographic projection of the first through hole on the first flexible layer, and the second through hole exposes the surface of the signal line away from the first flexible layer; and
a first conductive layer, comprising an adapter line, wherein the adapter line covers at least a sidewall of the second through hole and the surface of the signal line exposed by the second through hole.

2. The display panel according to claim 1, wherein the display panel further comprises:
an insulation layer, provided on a side of the inorganic layer away from the first flexible layer, wherein the insulation layer is provided with a third through hole, and the third through hole communicates with the second through hole;
wherein, an orthographic projection of the second through hole on the first flexible layer is located within an orthographic projection of the third through hole on the first flexible layer; and
the second through hole is provided with a second hole wall, the third through hole is provided with a third hole wall, the second hole wall and the third hole wall are connected to each other to form a through hole wall, and the through hole wall is at least provided with a stepped portion.

3. The display panel according to claim 1, wherein the display panel further comprises:
an insulation layer, provided on a side of the inorganic layer away from the first flexible layer, wherein the insulation layer is provided with a third through hole, and the third through hole communicates with the second through hole;
wherein, an orthographic projection of the second through hole on the first flexible layer is located within an orthographic projection of the third through hole on the first flexible layer;
the second through hole is provided with a second hole wall, the third through hole is provided with a third hole wall, a first distance parallel to a direction of the first flexible layer is provided between an end of the second hole wall away from the first flexible layer and an end of the third hole wall close to the flexible layer, and the first distance is greater than or equal to 0; and
the adapter line covers at least part of a surface of the insulation layer away from the first flexible layer, and at least covers the second hole wall and the third hole wall.

4. The display panel according to claim 3, wherein the insulation layer comprises a first gate insulation layer, and the first gate insulation layer is provided with the third through hole;
the first conductive layer further comprises a gate of a transistor and a first plate of a capacitor; and
the adapter line covers at least part of a surface of the first gate insulation layer away from the first flexible layer.

5. The display panel according to claim 3, wherein the insulation layer comprises a first gate insulation layer and a second gate insulation layer provided in sequence along a direction away from the first flexible layer, and the third through hole is provided in the first gate insulation layer and the second gate insulation layer;
the first conductive layer comprises a second plate of a capacitor; and
the adapter line covers at least part of a surface of the second gate insulation layer away from the first flexible layer.

6. The display panel according to claim 5, wherein the third through hole comprises a first through sub-hole and a second through sub-hole;
the first through sub-hole is provided in the first gate insulation layer, and the second through sub-hole is provided in the second gate insulation layer;
an orthographic projection of the first through sub-hole on the first flexible layer is located within an orthographic projection of the second through sub-hole on the first flexible layer; and
the first through sub-hole is provided with a first sub-hole wall, the second through sub-hole is provided with a second sub-hole wall, a second distance parallel to the direction of the first flexible layer is provided between an end of the first sub-hole wall away from the first flexible layer and an end of the second sub-hole wall close to the first flexible layer, and the second distance is greater than or equal to zero.

7. The display panel according to claim 3, wherein the display panel further comprises:
an active layer, provided between the inorganic layer and the insulation layer;
an interlayer dielectric layer, provided on a side of the first conductive layer away from the first flexible layer; and
a third conductive layer, provided on a side of the interlayer dielectric layer away from the first flexible layer, wherein the third conductive layer comprises a source and a drain of a transistor, the source and the drain are connected to the active layer, and the third conductive layer is connected to the adapter line;
wherein, the signal line is configured to provide a power supply voltage to a pixel circuit.

8. The display panel according to claim 1, wherein the display panel further comprises:
a buffer layer, provided between the first flexible layer and the second flexible layer;
wherein, the signal line is provided on a side of the buffer layer close to the first flexible layer.

9. The display panel according to claim 6, wherein the first distance is not less than 3 μm.

10. A method for manufacturing a display panel, comprising:
forming a first flexible layer;
forming a signal line on a side of the first flexible layer;
forming a second flexible layer on a side of the signal line away from the first flexible layer;
forming a first through hole in the second flexible layer, wherein the first through hole exposes a surface of the signal line away from the first flexible layer;
forming an inorganic layer on a side of the second flexible layer away from the first flexible layer, wherein the inorganic layer covers a surface of the second flexible layer away from the first flexible layer and a sidewall of the first through hole; and
forming a first conductive layer, wherein the first conductive layer comprises an adapter line;
wherein, a second through hole is formed in the inorganic layer, an orthographic projection of the second through hole on the first flexible layer is located with an orthographic projection of the first through hole on the first flexible layer, and the second through hole exposes the surface of the signal line away from the first flexible layer; and
the adapter line covers at least a sidewall of the second through hole and the surface of the signal line exposed by the second through hole.

11. The method for manufacturing the display panel according to claim 10, wherein, the method further comprises:
forming an insulation layer on a side of the inorganic layer away from the first flexible layer;
wherein, a third through hole is formed in the insulation layer, the insulation layer covers at least part of a surface of the inorganic layer, and the third through hole communicates with the second through hole;
an orthographic projection of the second through hole on the first flexible layer is located within an orthographic projection of the third through hole on the first flexible layer;
the second through hole is provided with a second hole wall, the third through hole is provided with a third hole wall, a first distance parallel to a direction of the first flexible layer is provided between an end of the second hole wall away from the first flexible layer and an end of the third hole wall close to the flexible layer, and the first distance is greater than or equal to 0; and
the adapter line covers at least part of a surface of the insulation layer away from the first flexible layer, and at least covers the second hole wall and the third hole wall.

12. The method for manufacturing the display panel according to claim 11, wherein the forming the insulation layer on the side of the inorganic layer away from the first flexible layer comprises:
forming a first gate insulation layer on a side of the inorganic layer away from the first flexible layer, wherein the first gate insulation layer covers at least part of a surface of the inorganic layer away from the first flexible layer; and
forming a second gate insulation layer on a side of the first gate insulation layer away from the first flexible layer, wherein the second gate insulation layer covers at least a part of a surface of the first gate insulation layer away from the first flexible layer;
wherein, a first through sub-hole is formed in the first gate insulation layer, a second through sub-hole is formed in the second gate insulation layer, and the first through sub-hole and the second through sub-hole form the third through hole;
an orthographic projection of the second through hole on the first flexible layer is located within an orthographic projection of the first through sub-hole on the first flexible layer, and an orthographic projection of the first through sub-hole on the first flexible layer is located within an orthographic projection of the second through sub-hole on the first flexible layer; and
the first through sub-hole is provided with a first sub-hole wall, the second through sub-hole is provided with a second sub-hole wall, a second distance parallel to the direction of the first flexible layer is provided between an end of the first sub-hole wall away from the first flexible layer and an end of the second sub-hole wall close to the first flexible layer, and the second distance is greater than or equal to zero.

13. A display device, comprising a display panel, comprising:
a first flexible layer;
a second flexible layer, provided on a side of the first flexible layer;
a signal line, provided between the first flexible layer and the second flexible layer, wherein the second flexible layer is provided with a first through hole, and the first through hole exposes a surface of the signal line away from the first flexible layer;
an inorganic layer, covering a surface of the second flexible layer away from the first flexible layer and a sidewall of the first through hole, wherein the inorganic layer is provided with a second through hole, an orthographic projection of the second through hole on the first flexible layer is located within an orthographic projection of the first through hole on the first flexible layer, and the second through hole exposes the surface of the signal line away from the first flexible layer; and
a first conductive layer, comprising an adapter line, wherein the adapter line covers at least a sidewall of the second through hole and the surface of the signal line exposed by the second through hole.

14. The display panel according to claim 1, wherein the display panel further comprises:
a buffer layer, provided between the first flexible layer and the second flexible layer;
wherein, the signal line is provided on a side of the buffer layer away from the first flexible layer.

15. The display panel according to claim 6, wherein the second distance is not smaller than 3 μm.

16. The display panel according to claim 6, wherein the first distance is not less than 3 μm, and the second distance is not smaller than 3 μm.

17. The display panel according to claim 3, wherein, in the condition that the first distance is equal to 0, the second hole wall and the third hole wall are connected to form a smooth sidewall.

18. The display panel according to claim 3, wherein, in the condition that the first distance is greater than 0, the third hole wall, a surface of the inorganic layer away from the first flexible layer and the second hole wall are connected to form at least one stepped portion.

19. The display panel according to claim 6, wherein, in the condition that the second distance is equal to 0, the first sub-hole wall and the second sub-hole wall are connected to form a smooth sidewall.

20. The display panel according to claim 6, wherein, in the condition that the second distance is greater than 0, the first sub-hole wall, a surface of the first gate insulation layer away from the first flexible layer and the second sub-hole wall are connected to form at least one stepped portion.
